(19) United States
(12) Patent Application Publication
(10) Pub. No.: US 2025/0233569 A1
(43) Pub. Date: Jul. 17, 2025

(54) PROGRAMMABLE GAIN AMPLIFIER AND CIRCUIT DEVICE

(71) Applicant: SEIKO EPSON CORPORATION, Tokyo (JP)

(72) Inventor: Yuto Goi, Matsumoto-shi (JP)

(21) Appl. No.: 19/015,024

(22) Filed: Jan. 9, 2025

(30) Foreign Application Priority Data
Jan. 11, 2024 (JP) 2024-002356

(51) Int. Cl. H03G 3/30; H03F 3/04

(52) U.S. Cl. CPC H03G 3/30; H03F 3/04; H03F 2200/372; H03G 2201/103

(57) ABSTRACT

A programmable gain amplifier includes: an input switch provided between an input node of an input signal and a first node; an operational amplifier; a sampling capacitor provided between the first node and an input terminal of the operational amplifier; a feedback capacitor provided between the input terminal and an output terminal; a reset switch provided in parallel with the feedback capacitor between the input terminal and the output terminal; and a noise cancellation circuit provided in parallel with the feedback capacitor and the reset switch between the input terminal and the output terminal and including a noise cancellation capacitor and a noise cancellation switch coupled in series.

The present application is based on, and claims priority from JP Application Serial Number 2024-002356, filed Jan. 11, 2024, the disclosure of which is hereby incorporated by reference herein in its entirety.

### BACKGROUND

### 1. Technical Field

The present disclosure relates to a programmable gain amplifier, a circuit device, and the like.

### 2. Related Art

According to the related art, a programmable gain amplifier that performs amplification with a variable gain is known. For example, JP-A-2012-114641 discloses a semiconductor device in which input pixel information is amplified by a programmable gain amplifier and converted into a digital value.

JP-A-2012-114641 is an example of the related art.

In the programmable gain amplifier, a kT/C noise generated in a capacitor on the input side is amplified by an amplifier. Therefore, there is a problem in that the capacitance value of the capacitor on the input side needs to be increased as much as possible in order to reduce the kT/C noise.

### SUMMARY

According to one aspect of the present disclosure, a programmable gain amplifier that amplifies a voltage difference between a first input signal and a second input signal with a variable gain is provided, the programmable gain amplifier including: a first input switch provided between a first input node of the first input signal and a first node; a second input switch provided between a second input node of the second input signal and the first node; an operational amplifier; a first sampling capacitor provided between the first node and a first input terminal of the operational amplifier; a first feedback capacitor provided between the first input terminal and a first output terminal of the operational amplifier and having a capacitance value that is variable according to the gain; a first reset switch provided in parallel with the first feedback capacitor between the first input terminal and the first output terminal; and a first noise cancellation circuit provided in parallel with the first feedback capacitor and the first reset switch between the first input terminal and the first output terminal and including a first noise cancellation capacitor and a first noise cancellation switch coupled in series.

According to another aspect of the present disclosure, a circuit device includes: the programmable gain amplifier described above; and an A/D converting circuit that performs A/D conversion of an output signal of the programmable gain amplifier.

### BRIEF DESCRIPTION OF THE DRAWINGS

FIG. 1 shows an example of the configuration of a programmable gain amplifier according to an embodiment.

FIG. 2 illustrates an operation the programmable gain amplifier.

FIG. 3 illustrates an operation in a sampling period.

FIG. 4 illustrates an operation in a noise cancellation period.

FIG. 5 illustrates an operation in an amplification period.

FIG. 6 shows an example of the configuration of a differential programmable gain amplifier.

FIG. 7 illustrates an operation of the differential programmable gain amplifier.

FIG. 8 illustrates an operation in a sampling period.

FIG. 9 illustrates an operation in a noise cancellation period.

FIG. 10 illustrates an operation in an amplification period.

FIG. 11 shows an example of the configuration in a comparative example.

FIG. 12 shows an example of noise characteristics.

FIG. 13 shows an example of the configuration of a circuit device according to the embodiment.

FIG. 14 illustrates an operation of A/D conversion.

FIG. 15 illustrates a problem of power supply noise.

FIG. 16 illustrates operations of the programmable gain amplifier and an A/D converting circuit.

FIG. 17 shows an example of output noise characteristics.

### DESCRIPTION OF EMBODIMENTS

An embodiment will now be described. The embodiment described below does not unduly limit the scope of the claims. Also, all of the elements described in the embodiment are not necessarily essential elements.

### 1. Programmable Gain Amplifier

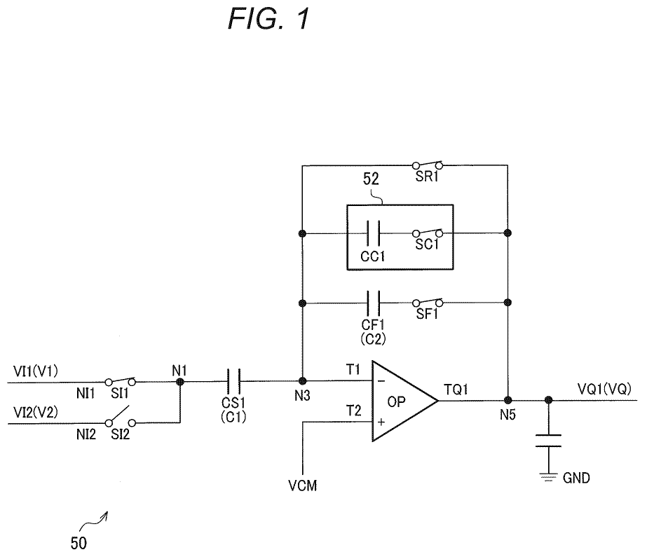

FIG. 1 shows an example of the configuration of a programmable gain amplifier 50 according to this embodiment. The programmable gain amplifier 50 is an amplifier that amplifies a voltage difference between an input signal VI1 and an input signal VI2 with a variable gain. For example, when the voltages of the input signals VI1 and VI2 are V1 and V2 and the gain is G, the programmable gain amplifier 50 outputs a signal of a voltage difference of G×(V1−V2) obtained by amplifying the voltage difference of V1−V2 with the gain G. In FIG. 1, an output signal VQ1 of the voltage of G×(V1−V2) is output, based on a ground GND as a reference.

The programmable gain amplifier 50 includes input switches SI1 and SI2, a sampling capacitor CS1, an operational amplifier OP, a feedback capacitor CF1, a noise cancellation circuit 52, and a reset switch SR1. The programmable gain amplifier 50 may also include a feedback switch SF1.

The noise cancellation circuit 52, which is a first noise cancellation circuit, includes a noise cancellation capacitor CC1 and a switch SC1. The input signals VI1 and VI2 are a first input signal and a second input signal, respectively, and the switches SI1 and SI2 are a first input switch and a second input switch, respectively. The capacitor CS1 is a first sampling capacitor, the capacitor CC1 is a first noise cancellation capacitor, and the capacitor CF1 is a first feedback capacitor. The switch SC1 is a first noise cancellation switch, the switch SR1 is a first reset switch, and the switch SF1 is a first feedback switch. The switches SI1, SI2, SF1, SC1, SR1 are configured with transistors such as MOS transistors. The other switches, described later, are similarly configured transistors with such as MOS transistors. The programmable gain amplifier 50 according to this embodiment is not limited to the configuration shown in FIG. 1, and various modifications can be made, such as omitting a part of the elements, adding other elements, and changing the elements to other types of elements.

In the programmable gain amplifier 50 having the configuration shown in FIG. 1, a thermal noise called a kT/C noise is generated and this causes a drop in accuracy. For example, a charge due to the kT/C noise at the timing when the reset switch SR1 turns from on to off is accumulated in the sampling capacitor CS1, and this causes a drop in the accuracy of the programmable gain amplifier 50. The kT/C noise changes according to the temperature and also changes due to the manufacturing variation of the transistor of the switch SR1, and therefore hinders improvement in accuracy. In this case, in order to suppress the drop in accuracy due to the kT/C noise, the capacitance value of the sampling capacitor CS1 may be increased, but this causes an increase in circuit area. Therefore, in this embodiment, the noise cancellation circuit 52 as shown in FIG. 1 is provided, thus reducing the kT/C noise and achieving both high accuracy and miniaturization of the programmable gain amplifier 50.

The configuration of the programmable gain amplifier 50 shown in FIG. 1 will be described in detail. The switch SI1, which is the first input switch, is provided between an input node NI1 of the input signal VIL and a node N1. For example, one end of the switch SI1 is coupled to the input node NI1, and the other end thereof is coupled to the node N1. The switch SI2, which is the second input switch, is provided between an input node NI2 of the input signal VI2 and the node N1. For example, one end of the switch SI2 is coupled to the input node NI2, and the other end thereof is coupled to the node N1. The input nodes NI1 and NI2 are a first input node and a second input node, respectively, and the node N1 is a first node. Also, modifications such as providing another circuit element between the input node NI1 or the input node NI2 and the node N1 may be made.

The operational amplifier OP is, for example, an amplifier having a differential input and a single output. The capacitor CS1, which is the first sampling capacitor, is provided between the node N1 and an input terminal T1 of the operational amplifier OP. In FIG. 1, the capacitance value of the sampling capacitor CS1 is C1. For example, one end of the capacitor CS1 is coupled to the node N1, and the other end thereof is coupled to the input terminal T1 of the operational amplifier OP. An input terminal T2 of the operational amplifier OP is set to have, for example, a common voltage VCM. The input terminal T1 is a first input terminal, and the input terminal T2 is a second input terminal. For example, the input terminal T1 is the inverting input terminal of the operational amplifier OP, and the input terminal T2 is the t non-inverting input terminal of the operational amplifier OP, but this is not limiting. Also, modifications such as providing another circuit element is provided between the capacitor CS1 and the input terminal T1 of the operational amplifier OP may be made.

The capacitor CF1, which is the first feedback capacitor, is provided between the input terminal T1 and an output terminal TQ1 of the operational amplifier OP. The capacitor CF1 is, for example, a capacitor having a capacitance value that is variable according to the gain of the programmable gain amplifier 50. In FIG. 1, the capacitance value of the feedback capacitor CF1 is C2. The output terminal TQ1 is a first output terminal, and the output signal VQ1 of the programmable gain amplifier 50 is output from the output terminal TQ1. The output signal VQ1 is, for example, a signal of a voltage difference obtained by amplifying the voltage difference between the input signal VI1 and the input signal VI2 with the gain of the programmable gain amplifier 50. The switch SF1, which is the first feedback switch, is provided in series with the feedback capacitor CF1 between the input terminal T1 and the output terminal TQ1 of the operational amplifier OP. For example, one end of the capacitor CF1 is coupled to the input terminal T1 of the operational amplifier OP, and the other end thereof is coupled to one end of the switch SF1. One end of the switch SF1 is coupled to the other end of the capacitor CF1, and the other end of the switch SF1 is coupled to the output terminal TQ1 of the operational amplifier OP. Also, modifications such as not providing the switch SF1 and using a circuit element such as another switch instead of the switch SF1 may be made.

The switch SR1, which is the first reset switch, is provided in parallel with the feedback capacitor CF1 and the like between the input terminal T1 and the output terminal TQ1 of the operational amplifier OP. For example, one end of the switch SR1 is coupled to the input terminal T1 of the operational amplifier OP, and the other end thereof is coupled to the output terminal TQ1 of the operational amplifier OP.

The noise cancellation circuit 52, which is the first noise cancellation circuit, is provided in parallel with the feedback capacitor CF1 and the reset switch SR1 between the input terminal T1 and the output terminal TQ1 of the operational amplifier OP. The noise cancellation circuit 52 includes the capacitor CC1 and the switch SC1 coupled in series. For example, one end of the capacitor CC1 is coupled to the input terminal T1 of the operational amplifier OP, and the other end thereof is coupled to the switch SC1. One end of the switch SC1 is coupled to the other end of the capacitor CC1, and the other end of the switch SC1 is coupled to the output terminal TQ1 of the operational amplifier OP. The capacitor CC1 is the first noise cancellation capacitor, and the switch SC1 is the first noise cancellation switch. Also, modifications such as providing another circuit element than the capacitors CF1, CC1 and the switches SF1, SC1, SR1 between the input terminal T1 and the output terminal TQ1 of the operational amplifier OP may be made.

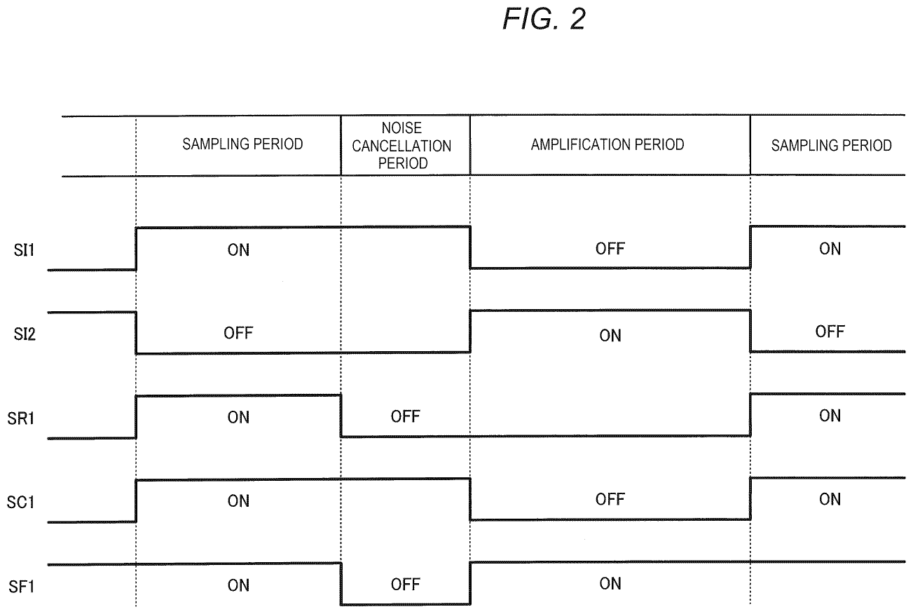

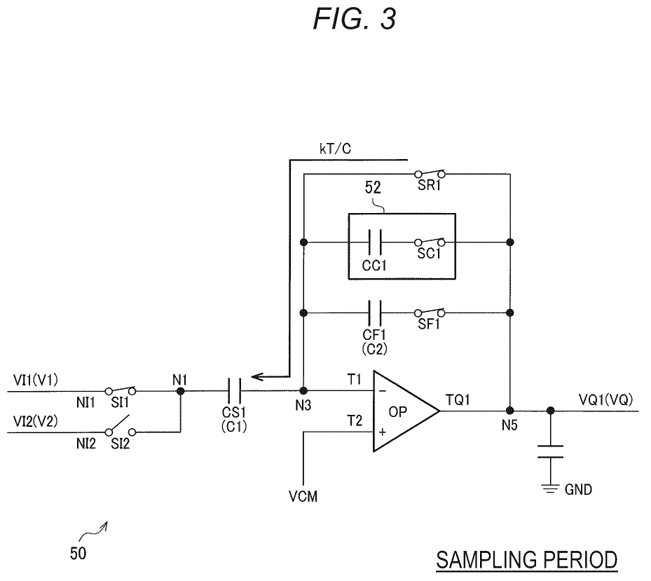

FIG. 2 illustrates an operation according to this embodiment, and FIGS. 3, 4, and 5 illustrate operations, showing the states of the switches of the programmable gain amplifier 50 during a sampling period, a noise cancellation period, and an amplification period, respectively. The amplification period may be referred to as a gain period or a gain operation period. FIG. 2 shows that each of the switches SI1, SI2, SR1, SC1, SF1 is on when a control signal input to each switch is at a high level, whereas each switch is off when the control signal is at a low level. The control signal is output from a control circuit, not shown, and this controls the on/off of each of the switches SI1, SI2, SR1, SC1, SF1. For example, the control signal is input to the gate of the transistor constituting each switch.

As shown in FIGS. 2 and 3, in the sampling period of the programmable gain amplifier 50, the switch SI1, which is the first input switch, is on, and the switch SI2, which is the second input switch, is off. The switch SR1, which is the first reset switch, and the switch SC1, which is the first noise cancellation switch, are on. The switch SF1, which is the first feedback switch, is on. When the sampling switch SI1 is on, charges corresponding to the input signal VI1, which is the first input signal, are accumulated in the sampling capacitor CS1. For example, the input terminal T2 of the operational amplifier OP is set to have the common voltage VCM, and a node N3 of the input terminal T1, too, is set to have the common voltage VCM via a virtual ground of the operational amplifier OP. Thus, when the voltage of the input signal VIL is V1, the capacitance value of the capacitor CS1 is C1, and the VCM is 0 V, charges corresponding to C1×V1 are accumulated in the sampling capacitor CS1. When the reset switch SR1 is on and the switches SC1 and SF1 are on, the charges accumulated in the capacitors CC1 and CF1 are reset to zero. At this time, the kT/C noise due to the ON resistance of the transistor of the switch SR1 is generated, and the potential of the node N3 of the input terminal T1 of the operational amplifier OP fluctuates due to this noise.

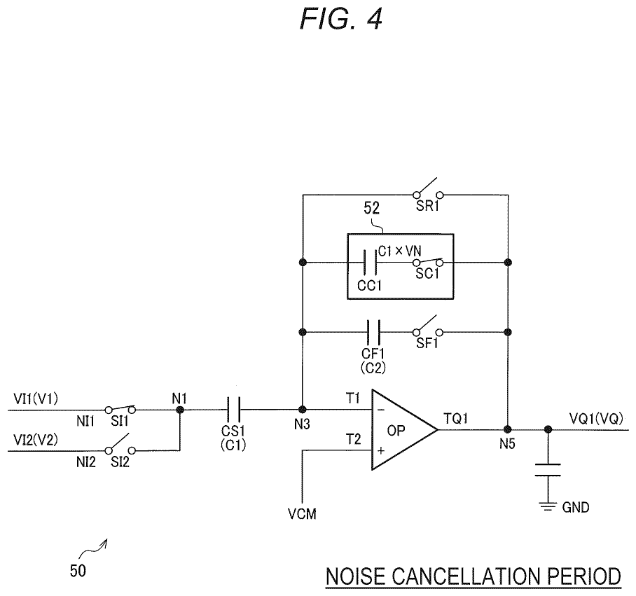

As shown in FIGS. 2 and 4, in the noise cancellation period after the sampling period, the reset switch SR1 is off. At this time, the feedback switch SF1 is off, too. In this case, the kT/C noise at the timing when the switch SR1 turns from on to off remains at the node N3. When this noise is expressed as VN, a charge QN=C1×VN due to the noise is accumulated in the noise cancellation capacitor CC1.

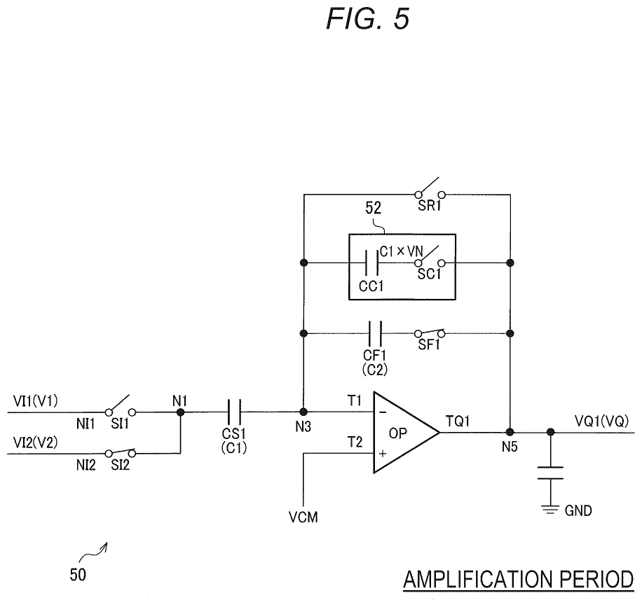

As shown in FIGS. 2 and 5, in the amplification period after the noise cancellation period, the input switch SI1 for the input signal VIL is off, and the input switch SI2 for the input signal VI2 is on. The noise cancellation switch SC1 is off. The feedback switch SF1 is on. In this amplification period, when the capacitance values of the capacitors CS1 and CF1 are C1 and C2, an amplification operation is performed with a gain expressed by G=C1/C2. That is, when the voltages of the input signals VIL and VI2 are V1 and V2, an amplification operation expressed by G×(V1−V2)=(C1/C2)×(V1−V2) is performed, and the output signal VQ1 of the voltage obtained by amplifying the voltage difference between the input signals VIL and VI2 with the gain G is output. That is, when the voltage of the output signal VQ1 is VQ, the signal output VQ1 of VQ=(C1/C2)×(V1−V2) is output.

In this case, if the noise cancellation circuit 52 as in this embodiment is not provided, the kT/C noise is superimposed on the output signal VQ1, but in this embodiment, the noise cancellation circuit 52 can cancel and reduce the kT/C noise. Specifically, in the noise cancellation period shown in FIG. 3, the charge QN=C1×VN is accumulated in the noise cancellation capacitor CC1, and the cancellation of the kT/C noise is thus achieved.

The noise cancellation operation according to this embodiment will now be described in more detail. In the sampling period shown in FIG. 3, the node N3 of the input terminal T1 is set to have the common voltage VCM=0 V via the virtual ground of the operational amplifier OP. Since the switch SI1 is on in FIG. 3, the charge of QS=C1×V1 is accumulated in the capacitor CS1. In this case, since the kT/C noise of the switch SR1 is generated, the charge accumulated at the node N3 can be expressed as −C1×V1−C1×VN. C1×VN, which is the charge due to the noise, fluctuates according to the temperature and the like.

In the noise cancellation period shown in FIG. 4, the switch SR1 turns from on to off, and the charge of −C1×V1−C1×VN is accumulated at the node N3. C1×VN in this case is the charge caused by the noise at the timing when the switch SR1 is turned off. Since the charge of −C1×V1 is accumulated on the node N3 side of the capacitor CS1, the charge of −C1×VN is accumulated on the node N3 side of the noise cancellation capacitor CC1, based on the law of conservation of charge. On the node N5 side of the capacitor CC1, the charge of C1×VN is accumulated. The node N5 is a node to which the output terminal TQ1 of the operational amplifier OP is coupled. That is, the charge of −C1×V1, of −C1×V1−C1×VN, which is the charge at the node N3, is accumulated on the node N3 side of the capacitor CS1, and the charge of −C1×VN is accumulated on the node N3 side of the capacitor CC1. As described above, in this embodiment, in the noise cancellation period shown in FIG. 4, C1×VN, which is the charge corresponding to the noise, is accumulated in the noise cancellation capacitor CC1.

In the amplification period shown in FIG. 5, the switch SI1 of the input signal VIL is off, and the switch SI2 of the input signal VI2 is on. Thus, when the voltage of the input signal VI2 is V2, the charge on the node N1 side of the capacitor CS1 is C1×V2, and the charge on the node N3 side is −C1×V2.

In the amplification period shown in FIG. 5, when the noise cancellation switch SC1 turns from on to off, the charge of −C1×VN is fixed to the node N3 side of the noise cancellation capacitor CC1, and the charge of C1×VN is fixed to the node N5 side.

That is, in the noise cancellation period shown in FIG. 4, since the voltage V1 of the input signal VIL is applied to one end of the sampling capacitor CS1, the charge on the node N3 side of the capacitor CS1 is −C1×V1. The charge on the node N3 side of the noise cancellation capacitor CC1 is −C1×VN. Thus, the charge at the node N3 in the noise cancellation period is expressed by the following formula (1).

$$- C 1 \times V 1 - C 1 \times VN \qquad ( 1 )$$

Meanwhile, in the amplification period shown in FIG. 5, since the voltage V2 of the input signal VI2 is applied to one end of the sampling capacitor CS1, the charge on the node N3 side of the capacitor CS1 is −C1×V2. The charge on the node N3 side of the capacitor CC1 is −C1×VN. When the voltage of the output signal VQ1 is VQ, the charge on the node N3 side of the capacitor CF1 is −C2×VQ. Thus, the charge at the node N3 in the amplification period is expressed by the following formula (2).

$$- C 1 \times V 2 - C 1 \times VN - C 2 \times VQ \qquad ( 2 )$$

Since the above formula (1) and the above formula (2) are equal to each other, based on the law of conservation of charge, the following equation (3) holds.

$$- C 1 \times V 1 - C 1 \times VN = - C 1 \times V 2 - C 1 \times VN - C 2 \times VQ \qquad ( 3 )$$

Thus, C1×VN, which is the charge due to the noise, is on both sides of the equation (3) and therefore cancelled, and the voltage VQ of the output signal VQ1 is expressed by the following equation (4).

$$VQ = ( C 1 / C 2 ) \times ( V 1 - V 2 ) \qquad ( 4 )$$

As described above, the programmable gain amplifier 50 according to this embodiment includes the input switches SI1 and SI2 for the input signals VI1 and VI2, the operational amplifier OP, the sampling capacitor CS1, the feedback capacitor CF1, the reset switch SR1, and the noise cancellation circuit 52. The input switches SI1 and SI2 are provided between the input nodes NI1 and NI2 of the input signals VI1 and VI2 and the node N1. The sampling capacitor CS1 is provided between the node N1 and the input terminal T1 of the operational amplifier OP. The feedback capacitor CF1 is a capacitor provided between the input terminal T1 and the output terminal TQ1 of the operational amplifier OP and having a capacitance value that is variable according to the gain G. The reset switch SR1 is provided in parallel with the feedback capacitor CF1 between the input terminal T1 and the output terminal TQ1 of the operational amplifier OP. The noise cancellation circuit 52 is provided in parallel with the feedback capacitor CF1 and the reset switch SR1 between the input terminal T1 and the output terminal TQ1 of the operational amplifier OP, and includes the noise cancellation capacitor CC1 and the switch SC1 coupled in series.

The programmable gain amplifier 50 according to this embodiment configured as described above can output the output signal VQ1 of the voltage VQ obtained by amplifying the voltage difference (V1−V2) between the input signals VI1 and VI2 with the variable gain G=C1/C2. In this embodiment, in the noise cancellation period shown in FIG. 4, the charge C1×VN due to the kT/C noise can be accumulated and held in the noise cancellation capacitor CC1 of the noise cancellation circuit 52. In the amplification period shown in FIG. 5, the charge due to the noise is accumulated in the noise cancellation capacitor CC1, and the noise can thus be cancelled in the amplification operation of the programmable gain amplifier 50. Thus, the noise can be reduced and a higher accuracy of the programmable gain amplifier 50 can be achieved. That is, the programmable gain amplifier 50 that can perform the amplification operation with a variable gain and that can reduce the noise can be achieved. Also, the kT/C noise can be reduced by increasing the capacitance value of the sampling capacitor CS1, but this causes an increase in the circuit area. In this regard, in this embodiment, the kT/C noise is cancelled by providing the noise cancellation circuit 52, and therefore the reduction in the noise can be achieved even without increasing the capacitance value of the sampling capacitor CS1. As an example, the capacitance value of the capacitor CS1, which is 10 to 20 pF up to this point, can be reduced to approximately 1 to 5 pF, and the circuit area can thus be reduced. Thus, the programmable gain amplifier 50 that can reduce the noise while reducing the circuit area and that can amplify the voltage difference between the input signals VI1 and VI2 with a variable gain can be achieved.

As described with reference to FIGS. 2 to 5, in this embodiment, in the sampling period, the input switch SI1 is on, the input switch SI2 is off, the reset switch SR1 and the noise cancellation switch SC1 are on. In the noise cancellation period, the reset switch SR1 is off, and in the amplification period, the input switch SI1 is off, the input switch SI2 is on, and the noise cancellation switch SC1 is off. In this way, in the sampling period, the input switch SI1 is on, and the charge based on the input signal VI1 is thus accumulated in the sampling capacitor CS1. In the noise cancellation period, the reset switch SR1 is off, and the charge based on the sampling noise can thus be accumulated in the noise cancellation capacitor CC1. In the amplification period, the input switch SI2 is on, and the charge based on the input signal VI2 is thus accumulated in the sampling capacitor CS1. Thus, the charge corresponding to the voltage difference between the input signals VIL and VI2 is accumulated in the feedback capacitor CF1, and the output signal VQ1 of the voltage based on the voltage difference can be output. In the amplification period, the charge due to the noise is accumulated in the noise cancellation capacitor CC1, and the noise can thus be cancelled in the amplification operation of the programmable gain amplifier 50.

The programmable gain amplifier 50 according to this embodiment also includes the feedback switch SF1 provided in series with the feedback capacitor CF1 between the input terminal T1 and the output terminal TQ1 of the operational amplifier OP. In this way, when the feedback switch SF1 is on, a feedback loop can be formed between the output terminal TQ1 and the input terminal T1 of the operational amplifier OP, and when the feedback switch SF1 is off, the feedback loop between the output terminal TQ1 and the input terminal T1 of the operational amplifier OP can be blocked.

As described with reference to FIGS. 2 to 5, in this embodiment, in the sampling period, the input switch SI1 is on, the input switch SI2 is off, the reset switch SR1 and the noise cancellation switch SC1 are on, and the feedback switch SF1 is on. In the noise cancellation period, the reset switch SR1 is off and the feedback switch SF1 is off, and in the amplification period, the input switch SI1 is off, the input switch SI2 is on, the noise cancellation switch SC1 is off, and the feedback switch SF1 is on. In this way, in the noise cancellation period shown in FIG. 4, as the feedback switch SF1 is off, the feedback loop between the output terminal TQ1 and the input terminal T1 of the operational amplifier OP is blocked and therefore the charge based on the sampling noise can be accumulated and held in the noise cancellation capacitor CC1. In the amplification period shown in FIG. 5, as the feedback switch SF1 is on, the feedback loop is formed and therefore the amplification operation based on the capacitance ratio between the sampling capacitor CS1 and the feedback capacitor CF1 can be achieved.

### 2. Differential Programmable Gain Amplifier

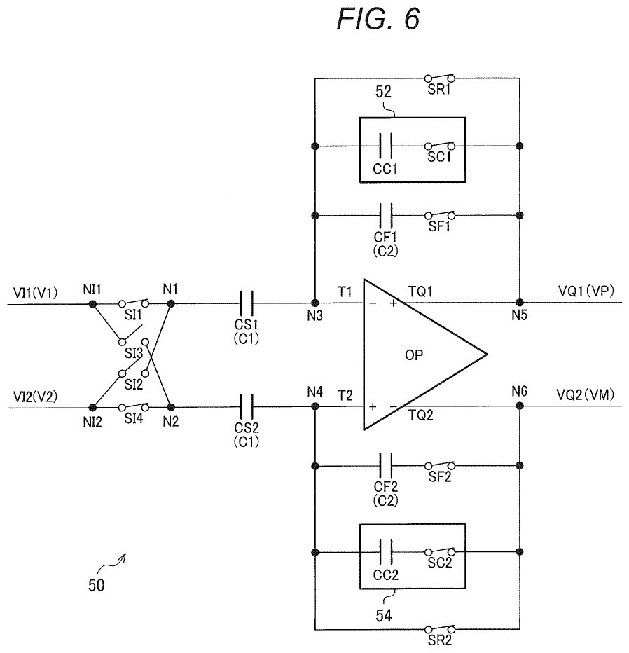

FIG. 6 shows an example of the configuration of a differential programmable gain amplifier 50. The differential programmable gain amplifier 50 shown in FIG. 6 also includes input switches SI3 and SI4, a sampling capacitor CS2, a feedback capacitor CF2, a reset switch SR2, and a noise cancellation circuit 54, in addition to the configuration shown in FIG. 1.

The switch SI3, which is a third input switch, is provided between the input node NI1 of the input signal VI1 and a node N2, and the switch SI4, which is a fourth input switch, is provided between the input node NI2 of the input signal VI2 and the node N2. The input nodes NI1 and NI2 are a first input node and a second input node, respectively, and the node N2 is a second input node.

The capacitor CF2, which is a second feedback capacitor, is a capacitor provided between the input terminal T2 and an output terminal TQ2 of the operational amplifier OP and having a capacitance value that is variable according to the gain. The gain can be expressed as G=C1/C2.

The input terminal T2 is a second input terminal, and the output terminal TQ2 is a second output terminal. In FIG. 6, the input terminals T1 and T2 are the inverting input terminal and the non-inverting input terminal of the operational amplifier OP, respectively, and the output terminals TQ1 and TQ2 are the non-inverting output terminal and the inverting output terminal of the operational amplifier OP, respectively, but this is not limiting.

The switch SR2, which is a second reset switch, is provided in parallel with the feedback capacitor CF2 between the input terminal T2 and the output terminal TQ2 of the operational amplifier OP.

The noise cancellation circuit 54, which is a second noise cancellation circuit, is provided in parallel with the feedback capacitor CF2 and the reset switch SR2 between the input terminal T2 and the output terminal TQ2 of the operational amplifier OP. The noise cancellation circuit 54 includes a noise cancellation capacitor CC2 and a switch SC2 coupled in series. The capacitor CC2 is a second noise cancellation capacitor, and the switch SC2 is a second noise cancellation switch.

In the programmable gain amplifier 50 of the differential configuration shown in FIG. 6, the voltage difference between the input signals VI1 and a VI2 is amplified with a variable gain, the output signal VQ1 is output from the node N5 of the output terminal TQ1 of the operational amplifier OP, and an output signal VQ2 is output from a node N6 of the output terminal TQ2. For example, the voltages of the output signals VQ1 and VQ2 are VP and VM. In this case, as will be described later, the programmable gain amplifier 50 shown in FIG. 6 can output the output signals VQ1 and VQ2 of the voltage difference VP−VM=2×(C1/C2)×(V1−V2) obtained by amplifying the voltage difference V1−V2 between the input signals VI1 and VI2 with the gain G=2×(C1/C2). Adopting the differential-input differential-output configuration in this manner enables a further reduction in the noise as compared with the programmable gain amplifier 50 of the differential-input single-output configuration shown in FIG. 1.

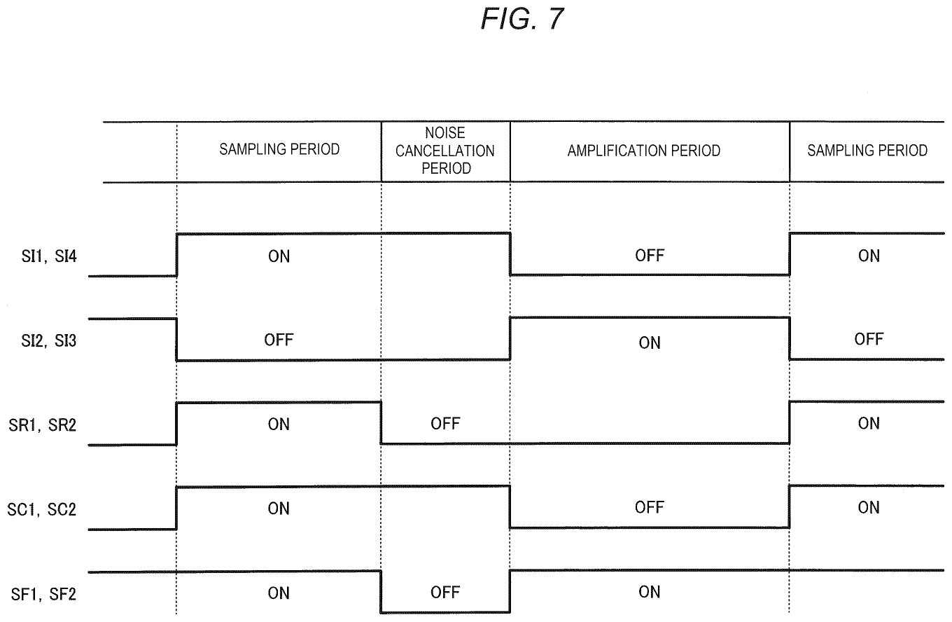

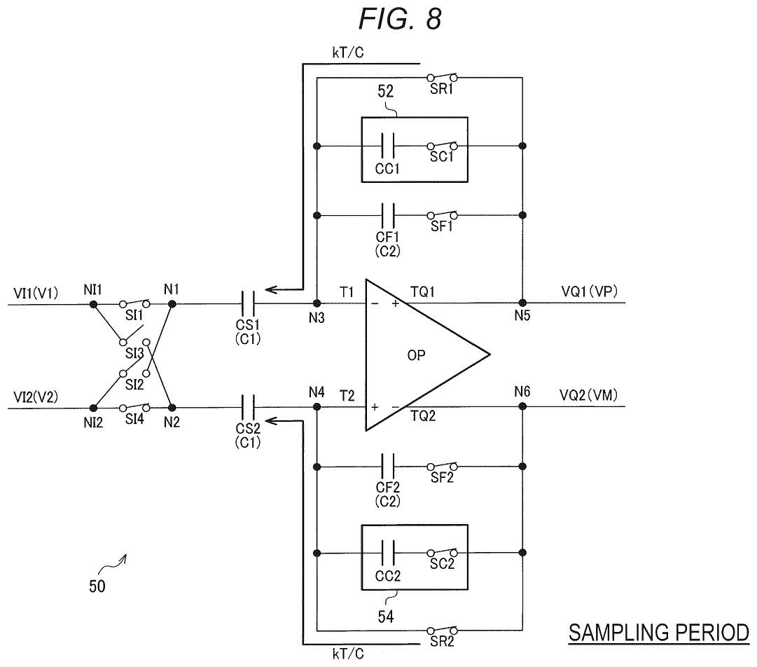

FIG. 7 illustrates an operation of the programmable gain amplifier 50 41 of the differential configuration, and FIGS. 8, 9, and 10 illustrate operations, showing the states of the switches during a sampling period, a noise cancellation period, and an amplification period, respectively.

As shown in FIGS. 7 and 8, in the sampling period, the switch SI1, which is the first input switch, and the switch SI4, which is the fourth input switch, are on, and the switch SI2, which is the second input switch, and the switch SI3, which is the third input switch, are off. The switch SR1, which is the first reset switch, the switch SR2, which is the second reset switch, the switch SC1, which is the first noise cancellation switch, and the switch SC2, which is the second noise cancellation switch, are on. The switch SF1, which is the first feedback switch, and the switch SF2, which is the second feedback switch, are on. As the switch SI1 is on, a charge corresponding to the input signal VI1 is accumulated in the capacitor CS1, and as the switch SI4 is on, a charge corresponding to the input signal VI2 is accumulated in the capacitor CS2. Thus, when the voltages of the input signals VIL and VI2 are V1 and V2, the capacitance values of the capacitors CS1 and CS2 are C1, and the VCM is 0 V, a charge corresponding to C1×V1 is accumulated in the capacitor CS1, and a charge corresponding to C1×V2 is accumulated in the capacitor CS2. As the switches SR1 and SR2 are on and the switches SC1, SC2, SF1, and SF2 are on, the charges accumulated in the capacitors CC1, CC2, CF1, and CF2 are reset to zero. At this time, a kT/C noise is generated due to the ON resistance of the transistors of the switches SR1 and SR2, and the potentials of the nodes N3 and N4 of the input terminals T1 and T2 of the operational amplifier OP fluctuate due to this noise.

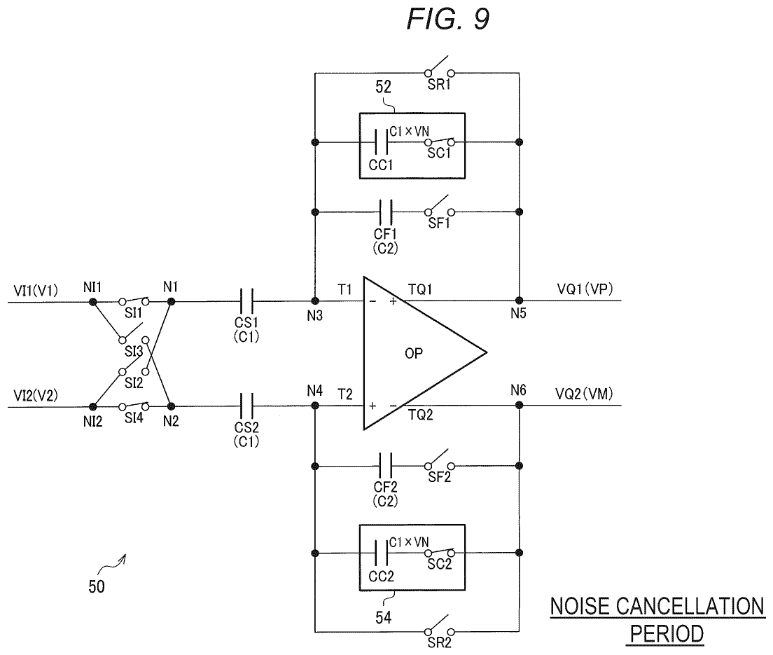

As shown in FIGS. 7 and 9, in the noise cancellation period, the reset switches SR1 and SR2 are off. At this time, the feedback switches SF1 and SF2 are off, too. In this case, the KT/C noise at the timing when the switches SR1 and SR2 turn from on to off remains at the nodes N3 and N4. When this noise is expressed as VN and the capacitance values of the capacitors CS1 and CS2 are C1, the charge QN=C1×VN due to noise is accumulated in the noise cancellation capacitors CC1 and CC2. For example, the nodes N3 and N4 of the input terminals T1 and T2 are set to have the common voltage VCM=0 V via the virtual ground of the operational amplifier OP or the like.

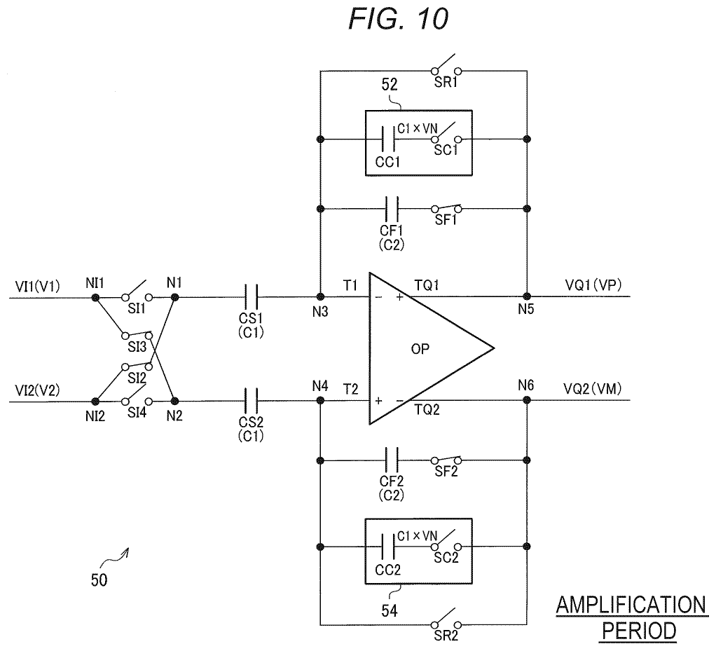

As shown in FIGS. 7 and 10, in the amplification period, the switches SI1 and SI4 are off, and the switches SI2 and SI3 are on. The noise cancellation switches SC1 and SC2 are off. The feedback switches SF1 and SF2 are on. In this amplification period, the amplification operation with the variable gain G is performed. For example, when the voltages of the input signals VIL and VI2 are V1 and V2, the programmable gain amplifier 50 can output the output signals VQ1 and VQ2 of the voltage difference obtained by amplifying the voltage difference V1−V2 between the input signals VI1 and VI2 with the gain G.

In this case, if the noise cancellation circuits 52 and 54 as in this embodiment are not provided, the kT/C noise is superimposed on the output signals VQ1 and VQ2, but in this embodiment, the noise cancellation circuits 52 and 54 can cancel and reduce the kT/C noise. Specifically, in the noise cancellation period shown in FIG. 9, the charge QN=C1×VN is accumulated in the noise cancellation capacitors CC1 and CC2, and the cancellation of the kT/C noise is thus achieved.

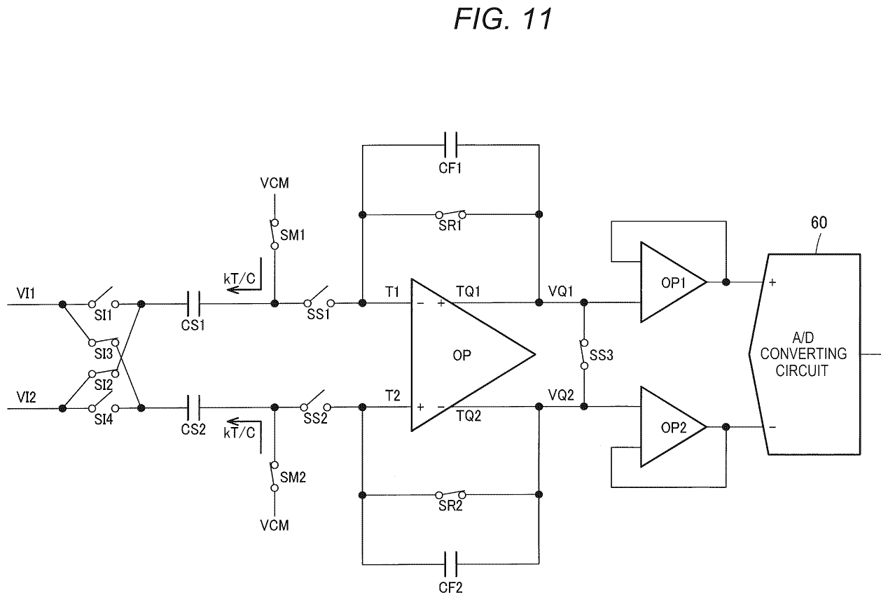

For example, FIG. 11 shows the configuration of a programmable gain amplifier in a comparative example of this embodiment. In the comparative example shown in FIG. 11, the noise cancellation circuits 52 and 54 as in this embodiment are not provided. Switches SS1, SS2, SM1, SM2, and SS3 are provided, and in the sampling period, the switches SM1, SM2, and SS3 are on, and the switches SS1 and ss2 are off. In FIG. 11, operational amplifiers OP1 and OP2 of voltage follower coupling to which the output signals VQ1 and VQ2 are input, and an A/D converting circuit 60 for A/D conversion of the output signals of the operational amplifiers OP1 and OP2, are provided. Such operational amplifiers OP1 and OP2 and A/D converting circuit 60 can be provided also in this embodiment shown in FIGS. 1 and 6. In the comparative example shown in FIG. 11, a kT/C noise is generated from the switches SM1 and SM2 to which the common voltage VCM is input at one end, and there is a problem in that this noise cannot be cancelled. In this regard, in this embodiment, since the noise cancelling circuits 52 and 54 are provided, the charge corresponding to kT/C noise is accumulated in the capacitors CC1 and CC2, and noise cancellation can be achieved during the amplification period, using the accumulated charge.

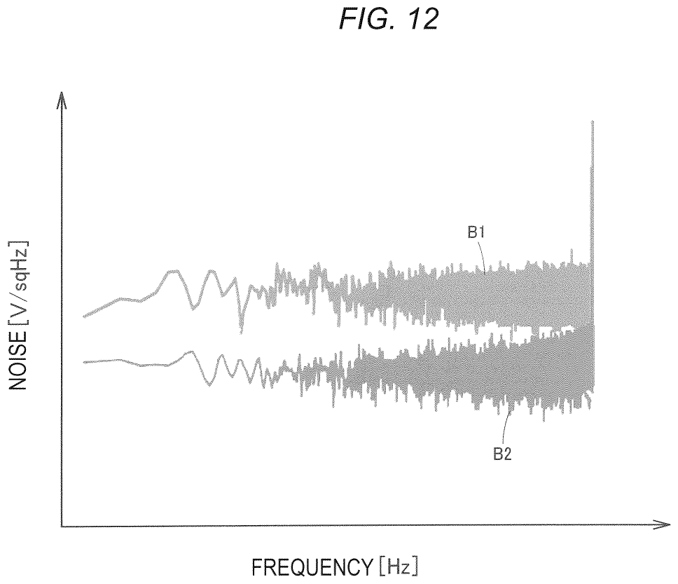

For example, B1 in FIG. 12 represents an example of noise characteristics of the programmable gain amplifier in the comparative example shown in FIG. 11, and B2 represents an example of noise characteristics in this embodiment. As indicated by B2 in FIG. 12, the noise can be significantly reduced in this embodiment as compared with the comparative example. For example, in the comparative example shown in FIG. 11, in order to reduce the kT/C noise, the capacitance values of the sampling capacitors CS1 and CS2 need to be increased, posing a problem in that the circuit size is increased. In contrast, in this embodiment, since noise can be cancelled by the noise cancellation circuits 52 and 54, the capacitance values of the sampling capacitors CS1 and CS2 need not be increased, which is advantageous in that the circuit area can be reduced as compared with the comparative example.

In the comparative example shown in FIG. 11, the switches SS1 and SS2 that are off in the sampling period are provided so that the charge due to the noise of the operational amplifier OP is not transmitted to and accumulated in the sampling capacitors CS1 and CS2 in the sampling period. In this regard, in this embodiment, noises including the noise of the operational amplifier OP can be cancelled, which is advantageous in that such switches SS1 and SS2 need not be provided.

As described above, in this embodiment, as described with reference to FIGS. 7 to 10, in the sampling period, the input switches SI1 and SI4 are on, the input switches SI2 and SI3 are off, the reset switches SR1 and SR2 and the noise cancellation switches SC1 and SC2 are on. In the noise cancellation period, the reset switches SR1 and SR2 are off, and in the amplification period, the input switches SI1 and SI4 are off, the input switches SI2 and SI3 are on, and the noise cancellation switches SC1 and SC2 are off. In this way, in the sampling period, since the input switches SI1 and SI4 are on, the charge based on the input signal VI1 is accumulated in the sampling capacitor CS1, and the charge based on the input signal VI2 is accumulated in the sampling capacitor CS2. In the noise cancellation period, since the reset switches SR1 and SR2 are off, the charge based on sampling noise can be accumulated in the noise cancellation capacitors CC1 and CC2. In the amplification period, since the input switches SI2 and SI3 are on, the charge based on the input signal VI2 is accumulated in the sampling capacitor CS1, and the charge based on the input signal VIL is accumulated in the sampling capacitor CS2. Thus, the charge corresponding to the voltage difference between the input signal VIL and the input signal VI2 is accumulated in the feedback capacitors CF1 and CF2, and the output signals VQ1 and VQ2 of the voltage based on the voltage difference can be output.

For example, the voltages of the output signals VQ1 and VQ2 are assumed to be VP and VM, respectively. In this case, the charge at the node N3 in the noise cancellation period shown in FIG. 9 is expressed by the following formula (5), and the charge at the node N3 in the amplification period shown in FIG. 10 is expressed by the following formula (6).

$$- C 1 \times V 1 - C 1 \times VN \qquad ( 5 )$$

$$- C 1 \times V 2 - C 1 \times VN - C 2 \times VP \qquad ( 6 )$$

Since the formula (5) and the formula (6) are equal to each other based on the law of conservation of charge at the node N3, the following equation (7) holds and the voltage VP of the output signal VQ1 is expressed by the following equation (8).

$$- C 1 \times V 1 - C 1 \times VN = - C 1 \times V 2 - C 1 \times VN - C 2 \times VP \qquad ( 7 )$$

$$VP = ( C 1 / C 2 ) \times ( V 1 - V 2 ) \qquad ( 8 )$$

The charge at the node N4 in the noise cancellation period shown in FIG. 9 is expressed by the following formula (9), and the charge at the node N4 in the amplification period shown in FIG. 10 is expressed by the following formula (10).

$$- C 1 \times V 2 - C 1 \times VN \qquad ( 9 )$$

$$- C 1 \times V 1 - C 1 \times VN - C 2 \times VM \qquad ( 10 )$$

Since the formula (9) and the formula (10) are equal to each other based on the law of conservation of charge at the node N4, the following equation (11) holds and the voltage VM of the output signal VQ2 is expressed by the following equation (12).

$$- C 1 \times V 2 - C 1 \times VN = - C 1 \times V 1 - C 1 \times VN - C 2 \times VM \qquad ( 11 )$$

$$VM = - ( C 1 / C 2 ) \times ( V 1 - V 2 ) \qquad ( 12 )$$

Thus, based on the equations (8) and (12), the voltage difference (VP−VM) between the output signals VQ1 and VQ2 is expressed by the following equation (13).

$$VP - VM = 2 \times ( C 1 / C 2 ) \times ( V 1 - V 2 ) \qquad ( 13 )$$

Thus, the differential programmable gain amplifier 50 shown in FIG. 6 can amplify the voltage difference (V1−V2) between the input signals VIL and VI2 to the voltage difference VP−VM=2×(C1/C2)×(V1−V2). For example, in the case of the configuration shown in FIG. 1, the gain is G=C1/C2, whereas in the differential configuration shown in FIG. 6, the gain can be doubled to G=2×(C1/C2) and the reduction in the noise or the like can be achieved.

For example, in the case of the comparative example shown in FIG. 11, the voltage VP of the output signal VQ1 is expressed by the following equation (14), and the voltage VM of the output signal VQ2 is expressed by the following equation (15). Thus, the voltage difference (VP−VM) between the output signals VQ1 and VQ2 is expressed by the following equation (16).

$$VP = ( C 1 / C 2 ) \times ( V 1 - V 2 ) + ( C 1 / C 2 ) \times VN \qquad ( 14 )$$

$$VM = - ( C 1 / C 2 ) \times ( V 1 - V 2 ) - ( C 1 / C 2 ) \times VN \qquad ( 15 )$$

$$VP - VM = 2 \times ( C 1 / C 2 ) \times ( V 1 - V 2 ) + 2 \times ( C 1 / C 2 ) \times VN \qquad ( 16 )$$

In this way, in the comparative example in which the noise cancellation circuits 52 and 54 are not provided, there is a problem in that the noise is multiplied by the capacitance ratio, such as 2×(C1/C2)×VN. For example, when the gain is changed, the noise also changes accordingly. In contrast, in the programmable gain amplifier 50 according to this embodiment, since the noise is cancelled as shown in the equation (13), such a problem can be prevented.

The programmable gain amplifier 50 according to this embodiment includes the feedback switch SF1 provided in series with the feedback capacitor CF1 between the input terminal T1 and the output terminal TQ1 of the operational amplifier OP, and the feedback switch SF2 provided in series with the feedback capacitor CF2 between the input terminal T2 and the output terminal TQ2 of the operational amplifier OP. In this way, when the feedback switches SF1 and SF2 are on, a feedback loop can be formed between the output terminal TQ1 and the input terminal T1 of the operational amplifier OP and between the output terminal TQ2 and the input terminal T2, and when the feedback switches SF1 and SF2 are off, the feedback loop can be blocked.

As described with reference to FIGS. 7 to 10, in this embodiment, in the sampling period, the input switches SI1 and SI4 are on, the input switches SI2 and SI3 are off, the reset switches SR1 and SR2 and the noise cancellation switches SC1 and SC2 are on, and the feedback switches SF1 and SF2 are on. In the noise cancellation period, when the reset switches SR1 and SR2 are off and the feedback switches SF1 and SF2 are off, and in the amplification period, the input switches SI1 and SI4 are off, the input switches SI2 and SI3 are on, the noise cancellation switches SC1 and SC2 are off, and the feedback switches SF1 and SF2 are on. In this way, in the noise cancellation period shown in FIG. 9, since the feedback switches SF1 and SF2 are off, the feedback loops between the output terminals TQ1 and TQ2 and the input terminals T1 and T2 of the operational amplifier OP are blocked, and the charge based on the sampling noise can be accumulated and held in the noise cancellation capacitors CC1 and CC2. In the amplification period shown in FIG. 10, since the feedback switches SF1 and SF2 are on, the feedback loop is formed and an amplification operation based on the capacitance ratio of the sampling capacitors CS1 and CS2 and the feedback capacitors CF1 and CF2 can be achieved.

### 3. Circuit Device

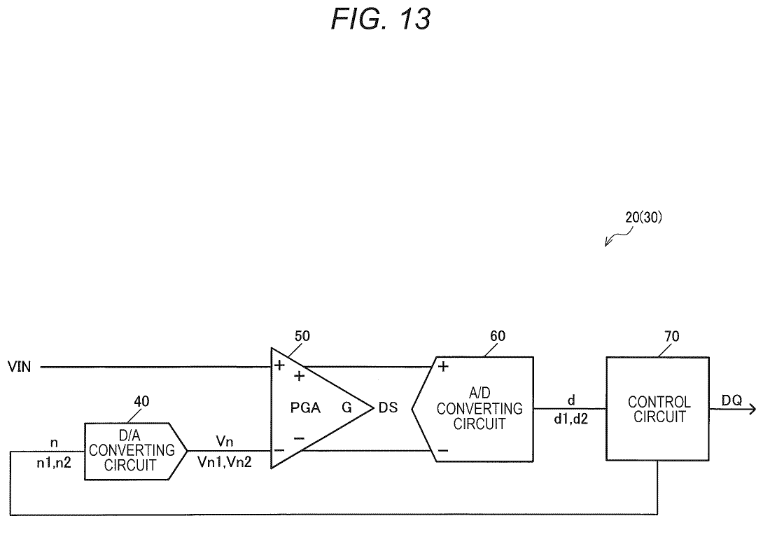

FIG. 13 shows an example of the configuration of a circuit device 20 including the programmable gain amplifier 50 according to this embodiment. The circuit device 20 includes the programmable gain amplifier 50 and an A/D converting circuit 60 that performs A/D conversion of an output signal of the programmable gain amplifier 50. In FIG. 13, the circuit device 20 also includes a D/A converting circuit 40 and a control circuit 70. The circuit device 20 shown in FIG. 13 implements an A/D converter 30 that performs A/D conversion of an input signal VIN and outputs ADC result data DQ. The circuit device 20 according to this embodiment is not limited to the configuration shown in FIG. 13 and various modifications can be made, such as omitting a part of the elements, adding other elements, and changing the elements to other types of elements. For example, a configuration in which the D/A converting circuit 40 and the control circuit 70 are not provided may be employed. In the description below, the circuit device 20 is referred to as the A/D converter 30 where appropriate.

The D/A converting circuit 40 performs D/A conversion of a DAC input digital value n and outputs a DAC output signal Vn. As the D/A converting circuit 40, for example, a resistor-ladder-type D/A converting circuit can be used.

The programmable gain amplifier 50 differentially amplifies the input signal VIN, which is an input voltage, and the DAC output signal Vn, which is a DAC output voltage. In FIG. 13, the programmable gain amplifier 50 differentially amplifies the input signal VIN and the DAC output signal Vn with the gain G, and outputs a difference signal DS, which is a differential voltage signal, to the A/D converting circuit 60. As such a programmable gain amplifier 50 is provided, the difference signal DS obtained by amplifying the difference between the input signal VIN and the DAC output signal Vn by the programmable gain amplifier 50 can be input to the A/D converting circuit 60. Thus, the A/D converting circuit 60 can perform A/D conversion, for example, on a full scale, on the difference signal DS in a wide amplitude range amplified by the programmable gain amplifier 50, and can achieve A/D conversion with high accuracy. For example, as the A/D converting circuit 60 performs A/D conversion of the signal amplified by the programmable gain amplifier 50, the A/D converter 30 having a higher resolution than the A/D converting circuit 60 can be implemented. The gain G of the programmable gain amplifier 50 may be, for example, approximately 10 to 20 times.

The A/D converting circuit 60 performs A/D conversion of the difference signal DS and outputs an ADC output digital value d. For example, the A/D converting circuit 60 receives a first difference signal of the difference signal DS input at a first input terminal of the differential input, receives a second difference signal of the difference signal DS input at a second input terminal of the differential input, and outputs the ADC output digital value d obtained by performing A/D conversion of the difference between the first difference signal and the second difference signal. The first difference signal and the second difference signal are, for example, the output signals VQ1 and VQ2 shown in FIG. 6, or signals obtained by buffering the output signals VQ1 and VQ2 to the operational amplifiers OP1 and OP2 of the voltage follower coupling as shown in FIG. 11. As the A/D converting circuit 60, for example, a successive approximation A/D converting circuit can be used. However, in this embodiment, an A/D converting circuit of another type such as a pipeline type or a delta-sigma type other than the successive approximation type may be used as the A/D converting circuit 60.

The control circuit 70 outputs the DAC input digital value n. For example, the control circuit 70 outputs the DAC input digital value n, based on the ADC output digital value d from the A/D converting circuit 60. For example, the control circuit 70 performs arithmetic processing based on the ADC output digital value d and outputs the DAC input digital value n to the D/A converting circuit 40. The control circuit 70 outputs the final ADC result data DQ. That is, the digital value of the ADC result data DQ is output. The control circuit 70 can be implemented by a logic circuit.

Specifically, the control circuit 70 outputs a DAC input digital value n1 and a DAC input digital value n2 different from the DAC input digital value n1, as the DAC input digital value n. The DAC input digital value n1 is a first DAC input digital value, and the DAC input digital value n2 is a second DAC input digital value. Then, the control circuit 70 finds the ADC result data DQ, based on an ADC output digital value d1, which is the ADC output digital value d obtained corresponding to the DAC input digital value n1, an ADC output digital value d2 which is the ADC output digital value d obtained corresponding to the DAC input digital value n2, and the DAC input digital value n. For example, when one of the DAC input digital values n1 and n2 is found from the other, the control circuit 70 finds the ADC result data DQ from the ADC output digital value d1, the ADC output digital value d2, the DAC input digital value n1 or the DAC input digital value n2. The ADC output digital value d1 is a first ADC output digital value, and the ADC output digital value d2 is a second ADC output digital value.

For example, when the control circuit 70 outputs the DAC input digital value n1, the D/A converting circuit 40 performs D/A conversion of the DAC input digital value n1 and outputs the DAC output signal Vn=Vn1. Then, the programmable gain amplifier 50 outputs the difference signal DS based on the difference between the input signal VIN and the DAC output signal Vn1, and the A/D converting circuit 60 performs A/D conversion of the difference signal DS and thus outputs the ADC output digital value d=d1 to the control circuit 70. When the control circuit 70 outputs the DAC input digital value n2, the D/A converting circuit 40 performs D/A conversion of the DAC input digital value n2 and outputs the DAC output signal Vn=Vn2. Then, the programmable gain amplifier 50 outputs the difference signal DS based on the difference between the input signal VIN and the DAC output signal Vn2, and the A/D converting circuit 60 performs A/D conversion of the difference signal DS and thus outputs the ADC output digital value d=d2 to the control circuit 70. The control circuit 70 then finds the ADC result data DQ, based on the ADC output digital values d1 and d2 and the DAC input digital value n. For example, the control circuit 70 finds the ADC result data DQ, based on the ADC output digital values d1 and d2 and the DAC input digital value n1 or the DAC input digital value n2, and outputs the ADC result data DQ as a digital value of the final ADC result.

In this way, the A/D converter 30 shown in FIG. 13 performs A/D conversion, for example, twice, such as A/D conversion based on the DAC input digital value n1 and A/D conversion based on the DAC input digital value n2. Then, the final ADC result data DQ is calculated, based on the ADC output digital value d1, which is the A/D conversion result based on the DAC input digital value n1, and the ADC output digital value d2, which is the A/D conversion result based on the DAC input digital value n2. The ADC output digital value d1 is found by A/D conversion by the A/D converting circuit 60 of the difference between the input signal VIN and the DAC output signal Vn1 obtained by D/A conversion of the DAC input digital value n1 by the D/A converting circuit 40. The ADC output digital value d2 is found by A/D conversion by the A/D converting circuit 60 of the difference between the input signal VIN and the DAC output signal Vn2 obtained by D/A conversion of the DAC input digital value n2 by the D/A converting circuit 40. Thus, the A/D converter 30 that can perform A/D conversion with higher accuracy than the resolution of the A/D converting circuit 60 can be implemented using the A/D converting circuit 60 and the D/A converting circuit 40. As an example, when the resolution of the A/D converting circuit 60 is, for example, 15 to 16 bits, the resolution can be improved, for example, by about 2 bits, and the A/D converter 30 having a resolution of, for example, 17 to 18 bits, can be implemented.

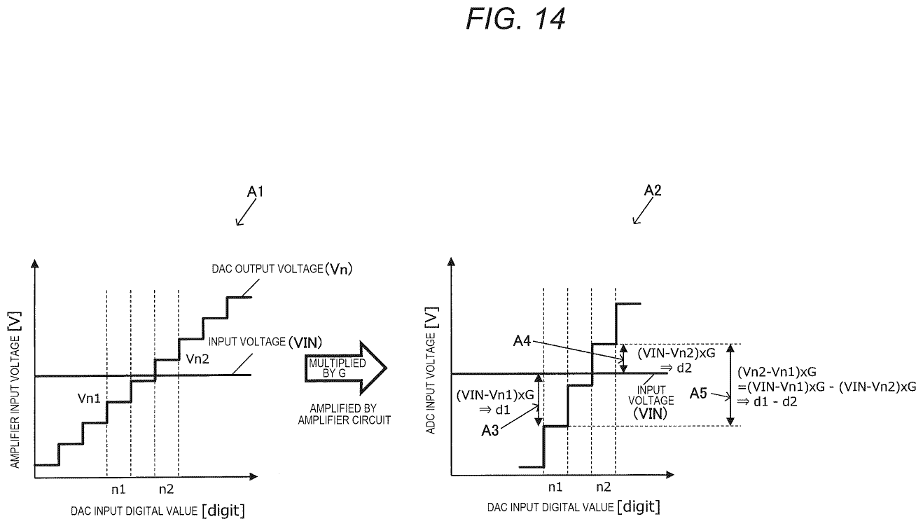

FIG. 14 illustrates an operation of the A/D converter 30. A1 in FIG. 14 shows the relationship between the input voltage and the DAC output voltage. The input voltage is the voltage of the input signal VIN, and the DAC output voltage is the voltage of the DAC output signal Vn. The DAC input digital value n on the horizontal axis of A1 in FIG. 14 is the digital value input to the D/A converting circuit 40, and the digital value is also called a digital code. As indicated by A1 in FIG. 14, when the DAC input digital value n1 is input, the D/A converting circuit 40 outputs the DAC output voltage of Vn1 to the programmable gain amplifier 50, and when the DAC input digital value n2 is input, the D/A converting circuit 40 outputs the DAC output voltage of Vn2 to the programmable gain amplifier 50. In A1 of FIG. 14, VIN, which is the input voltage of the A/D converter 30, is, for example, a voltage between the DAC output voltages Vn1 and Vn2. In this embodiment, the input signal VIN is referred to as an input voltage, where appropriate, the D/A converting circuit 40 is referred to as a DAC, where appropriate, and the A/D converting circuit 60 is referred to as an ADC, where appropriate.

A2 in FIG. 14 shows the relationship between the input voltage and the ADC input voltage after the amplification by the programmable gain amplifier 50. The ADC input voltage is a differential voltage, which is the voltage of the difference signal DS. In A2 in FIG. 14, signal amplification with a multiplication by G, where G>1, is performed by the programmable gain amplifier 50.

As indicated by A1 in FIG. 14, when the DAC input digital value n1 is input, the D/A converting circuit 40 outputs the output voltage Vn1. Then, as indicated by A2 in FIG. 14, the programmable gain amplifier 50 amplifies VIN-Vn1, which is the difference voltage between the input voltage VIN and the DAC output voltage Vn1, to G times, and outputs the signal to the A/D converting circuit 60, and the A/D converting circuit 60 performs A/D conversion of the voltage of (VIN−Vn1)×G and outputs the ADC output digital value d1 to the control circuit 70. As indicated by A1 in FIG. 14, when the DAC input digital value n2 is input, the D/A converting circuit 40 outputs the output voltage Vn2. Then, as indicated by A2 in FIG. 14, the programmable gain amplifier 50 amplifies VIN-Vn2, which is the difference voltage between the input voltage VIN and the output voltage Vn2, to G times, and outputs the signal to the A/D converting circuit 60, and the A/D converting circuit 60 performs A/D conversion of the voltage of (VIN−Vn2)×G and outputs the ADC output digital value d2 to the control circuit 70.

Then, the control circuit 70 finds the ADC result data DQ, based on the ADC output digital value d1 input from the A/D converting circuit 60 when the DAC input digital value n1 is output to the D/A converting circuit 40, and the ADC output digital value d2 input from the A/D converting circuit 60 when the DAC input digital value n2 is output to the D/A converting circuit 40. For example, the difference voltage indicated by A3 in FIG. 14 is expressed by (VIN−Vn1)×G, which corresponds to the ADC output digital value d1. The difference voltage indicated by A4 is expressed by (VIN−Vn2)×G, which corresponds to the ADC output digital value d2. The differential voltage indicated by A5 is expressed by (Vn2−Vn1)×G=(VIN−Vn1)×G−(VIN−Vn2)×G, which corresponds to the difference d1−d2 between the ADC output digital values d1 and d2. Thus, VIN, which is the input voltage of the A/D converter 30, can be specified from the ratio of the difference voltage of A3 and the differential voltage of A4 to the differential voltage of A5. Specifically, VIN can be specified by the following equation (17).

$$VIN = Vn 1 + ( Vn 2 - Vn 1 ) \times \{ d 1 / ( d 1 - d 2 ) \} \qquad ( 17 )$$

Here, d1=G×(VIN−Vn1) and d2=G×(VIN−Vn2).

Thus, the control circuit 70 can calculate and output the ADC result data DO as expressed by the following equation (18).

$$DQ = n 1 + ( n 2 - n 1 ) \times \{ d 1 / ( d 1 - d 2 ) \} \qquad ( 18 )$$

For example, when VIN is a voltage between Vn1 and Vn2, VIN is a voltage expressed by a ratio of d1/(d1−d2) between Vn1 and Vn2. For example, when d1/(d1−d2) is 0.5, VIN=Vn1+(Vn2−Vn1)×0.5, and VIN is a voltage that is the median between Vn1 and Vn2. When d1/(d1−d2) is 0.6, VIN=Vn1+(Vn2−Vn1)×0.6, and VIN is a voltage expressed by a ratio of 60% between Vn2 and Vn1. Even when VIN is not a voltage between Vn1 and Vn2, VIN can be specified by the equation (17), and the control circuit 70 can find and output the ADC result data DQ as in the equation (18).

According to this embodiment, for example, even when the programmable gain amplifier 50 is provided at the stage preceding the A/D converting circuit 60 in order to improve the resolution of the A/D conversion, the circuit characteristics of the programmable gain amplifier 50, which is an amplifier circuit, are less likely to affect the result of the A/D conversion. For example, as shown in the above equations (17) and (18), theoretically, the gain G of the programmable gain amplifier 50 does not affect the result of the A/D conversion. In this embodiment, the control circuit 70 generates the DAC input digital value n, based on the ADC output digital value d from the A/D converting circuit 60. For example, the control circuit 70 generates the DAC input digital value n by feedback control. As such feedback control is performed, VN, which is the DAC output voltage of the D/A converting circuit 40, can be brought close to VIN, which is the input voltage. For example, when VN and VIN are too far from each other, it is difficult to acquire an accurate A/D conversion result, but when VN is brought close to VIN, a higher accuracy of the AD conversion result can be achieved.

### 4. Power Supply Noise

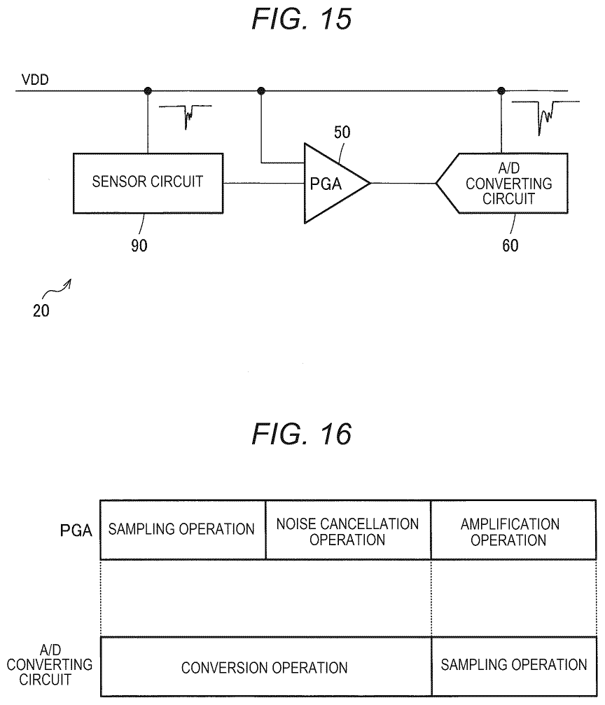

FIG. 15 shows an example of the configuration of the circuit device 20 according to this embodiment including a sensor circuit 90. The circuit device 20 includes a programmable gain amplifier 50, an A/D converting circuit 60 that performs A/D conversion on an output signal of the programmable gain amplifier 50, and a sensor circuit 90 that outputs a detection signal to the programmable gain amplifier 50 as the input signal VIL or the input signal VI2. The input signals VI1 and VI2 are a first input signal and a second input signal, respectively. In the case of FIG. 13 as an example, the detection signal of the sensor circuit 90 is input to the programmable gain amplifier 50 as VIN, which is the input signal VIL or the input signal VI2. In the circuit device 20 having such a configuration, the A/D converting circuit 60 performs A/D conversion of a signal obtained by amplifying the detection signal of the sensor circuit 90 by the programmable gain amplifier 50 and thus can output a digital A/D conversion result.

The sensor circuit 90 is a circuit that detects a physical quantity and outputs a detection signal. When the detected physical quantity is a temperature, the sensor circuit 90, which is a temperature sensor circuit, detects the temperature and outputs a temperature detection signal. For example, the sensor circuit 90 outputs a temperature-dependent voltage that changes according to the temperature in the environment, as the detection signal. For example, the temperature sensor circuit 90 generates the detection signal, using circuit a element having temperature dependence. Specifically, the temperature sensor circuit 90 outputs a temperature detection voltage having a voltage value that changes depending on the temperature, as the detection signal, by using the temperature dependence of a forward voltage of a PN junction. As the programmable gain amplifier 50 amplifies the detection signal, which is the temperature detection voltage, and the A/D converting circuit 60 performs A/D conversion of the amplified signal, a digital-output temperature sensor can be implemented. For example, in the circuit device 20 according to this embodiment, A/D conversion with higher accuracy than the resolution of the A/D converting circuit 60 can be performed and therefore a demand for an output of a highly accurate temperature detection result can be met. While the digital-output temperature sensor needs to output a highly accurate temperature detection result over a wide range, in the circuit device 20 according to this embodiment, the range can be widened easily and therefore a demand for an output of a highly accurate temperature detection result over a wide range can be met. The physical quantity detected by the sensor circuit 90 is not limited to temperature and may be physical quantities such as acceleration, angular velocity, distance or pressure.

In FIG. 15, a power supply voltage based on a common power supply VDD is supplied to the A/D converting circuit 60 and the sensor circuit 90. For example, in the circuit device 20 according to this embodiment, a power supply circuit, not illustrated, is provided, and the power supply circuit generates a power supply voltage based on the VDD and supplies the power supply voltage to the A/D converting circuit 60 and the sensor circuit 90. The power supply circuit also supplies the power supply voltage to the programmable gain amplifier 50. In this case, the power supply voltage supplied to the A/D converting circuit 60, the sensor circuit 90, and the programmable gain amplifier 50 may be a power supply voltage formed by regulating the VDD by a regulator of the power supply circuit. For example, the power supply voltage supplied to the A/D converting circuit 60, the sensor circuit 90, and the like, may be different power supply voltages. For example, a first regulator for the A/D converting circuit 60 and a second regulator for the sensor circuit 90 may be provided in the power supply circuit, and power supply voltages formed by regulating the VDD by the first regulator and the second regulator may be supplied to the A/D converting circuit 60 and the sensor circuit 90.

In the case of the configuration shown in FIG. 15, there is a problem in that a noise generated in the A/D conversion operation of the A/D converting circuit 60 is transmitted to the sensor circuit 90 via the common power supply VDD, causing a drop in the detection accuracy of the sensor circuit 90, or the like.

In this embodiment, as shown in FIG. 16, the A/D converting circuit 60 performs the conversion operation in a period during which the programmable gain amplifier 50 performs the sampling operation. For example, in the sampling period of the programmable gain amplifier 50, the

A/D converting circuit 60 performs an A/D conversion operation such as sequential A/D conversion. The A/D converting circuit 60 may perform the A/D conversion operation in the noise cancellation period of the programmable gain amplifier 50. In a period during which the programmable gain amplifier 50 performs the amplification operation, the A/D converting circuit 60 performs the sampling operation. For example, in the amplification period of the programmable gain amplifier 50, the A/D converting circuit 60 performs a signal sampling operation based on the output signal of the programmable gain amplifier 50. For example, the A/D converting circuit 60 has a sampling capacitor and performs an operation of sampling a signal based on the output signal of the programmable gain amplifier 50 to the sampling capacitor. The signal based on the output signal is the output signal or a signal obtained by buffering the output signal by an operational amplifier of voltage follower coupling, or the like. The A/D converting circuit 60 performs the A/D conversion operation based on the sampled voltage, and outputs the A/D-converted digital data. In this way, the sampling period of the programmable gain amplifier 50 can be ended early, and the adverse effect of the noise generated in the A/D converting circuit 60 after the end timing of the sampling period on the final A/D conversion result can be reduced. For example, the sampling period can be changed to any period and the adverse effect of fluctuations of the power supply VDD can be reduced. For example, in this embodiment, as described above, since the capacitance values of the sampling capacitors CS1 and CS2 can be reduced by cancelling the kT/C noise, there is an advantage in that the programmable gain amplifier 50 can sample the detection signal of the sensor circuit 90 in a short sampling period. Thus, the sampling period of the programmable gain amplifier 50 can be ended in a short time, and the noise generated in the A/D conversion operation after the end of the sampling period can be suppressed from adversely affecting the final A/D conversion result.

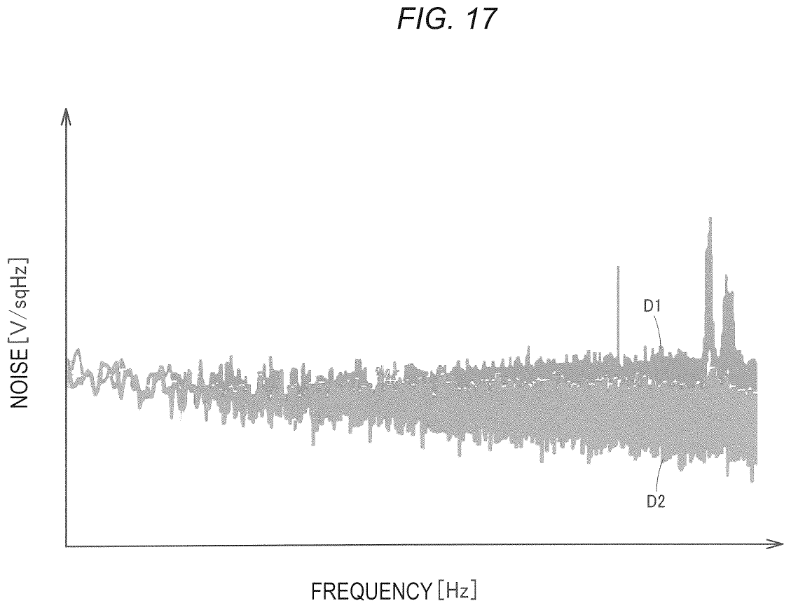

For example, FIG. 17 shows an example of final noise characteristics in the circuit device 20 shown in FIG. 15. D1 in FIG. 17 shows an example of noise characteristics in the case of the comparative example shown in FIG. 11, and D2 shows an example of noise characteristics in the case of this embodiment. As indicated by D2 in FIG. 17, according to this embodiment, the noise in the final result such as temperature detection data can be significantly reduced as compared with the comparative example.

As the A/D converting circuit 60, for example, a successive approximation A/D converting circuit can be used. In the case of the successive approximation type, the A/D converting circuit 60 can include a SAR circuit, a D/A converting circuit, a sample and hold circuit, and a comparator. The SAR circuit has a successive approximation register in which a register value is set, based on a comparison result signal from the comparator, and outputs successive approximation data to the D/A converting circuit. The D/A converting circuit performs D/A conversion of the successive approximation data, and outputs a DAC output signal corresponding to the successive approximation data to the comparator. The comparator, which is a comparison circuit, compares an input signal sampled and held by the sample and hold circuit with the DAC output signal from the D/A converting circuit, and outputs a comparison result signal to the SAR circuit. When the comparator performs successive approximation processing from the MSB bit to the LSB bit, the result of the comparison processing with each bit is stored as each register value of the successive approximation register provided in the SAR circuit. The SAR circuit then outputs a final A/D conversion result signal based on the successive approximation. As the D/A converting circuit of the successive approximation A/D converting circuit 60, for example, a charge-distribution-type D/A converting circuit, which is a capacitor array type, can be used, and in this case, the function of the sample and hold circuit is actually implemented by the D/A converting circuit. The charge-redistribution-type D/A converting circuit is implemented, for example, by a comparator with a non-inverting input terminal set to have a common voltage, a capacitor array and a switch array coupled in series to an inverting input terminal of the comparator, and a control circuit which performs on/off control of a plurality of switches of the switch array, or the like. When the successive approximation A/D converting circuit is used as the A/D converting circuit 60 in this way, A/D conversion over a wide range can be performed.

The circuit device 20 according to this embodiment can be used as a circuit device of an oscillator. The oscillator includes a resonator and the circuit device 20. The resonator is electrically coupled to the circuit device 20. The resonator and the circuit device 20 are electrically coupled to each other, for example, using an internal wiring of a package for housing the resonator and the circuit device 20, a bonding wire, or a metal bump or the like. The resonator is an element that generates mechanical resonation, based on an electrical signal. For example, the resonator can be implemented by a resonator element such as a quartz crystal resonator element. The circuit apparatus 20 is, for example, an integrated circuit (IC) manufactured by a semiconductor process and is, for example, a semiconductor chip having a circuit element formed at the top of a semiconductor substrate. The circuit device 20 in this case includes an oscillation circuit and an output circuit. The oscillation circuit is a circuit that causes the resonator to oscillate. The output circuit outputs a clock signal based on an oscillation signal of the oscillation circuit. For example, the output circuit buffers the oscillation signal and outputs the oscillation signal as a clock signal. The circuit device 20 including the sensor circuit 90 described with reference to FIG. 15 detects the ambient temperature of the resonator, and outputs ADC result data as temperature detection data. In this way, the circuit device 20 that can detect the ambient temperature of the resonator and output the temperature detection data can be implemented. In this case, for example, a PLL loop or the like may be built by an external system, and the temperature compensation of the oscillation frequency of the resonator may be performed, based on the temperature detection data, thus implementing the temperature compensation of the clock signal.

As described above, the programmable gain amplifier according to this embodiment, which amplifies a voltage difference between a first input signal and a second input signal with a variable gain, includes a first input switch provided between a first input node of the first input signal and a first node, a second input switch provided between a second input node of the second input signal and the first node, and an operational amplifier. The programmable gain amplifier also includes a first sampling capacitor provided between the first node and the first input terminal of the operational amplifier, a first feedback capacitor provided between the first input terminal and a first output terminal of the operational amplifier and having a capacitance value that is variable according to the gain, and a first reset switch provided in parallel with the first feedback capacitor between the first input terminal and the first output terminal. The programmable gain amplifier also includes a first noise cancellation circuit provided in parallel with the first feedback capacitor and the first reset switch between the first input terminal and the first output terminal and including a first noise cancellation capacitor and a first noise cancellation switch coupled in series.

According to this embodiment, the output signal of the voltage obtained by amplifying the voltage difference between the first input signal and the second input signal with a variable gain can be output. In this embodiment, for example, the charge due to the sampling noise can be accumulated and held in the first noise cancellation capacitor of the first noise cancellation circuit. Since the charge due to the noise is accumulated in the first noise cancellation capacitor, the noise can be cancelled in the amplification operation of the programmable gain amplifier. This can reduce noise and achieve higher accuracy of the programmable gain amplifier.

In this embodiment, in a sampling period, the first input switch may be on, the second input switch may be off, and the first reset switch and the first noise cancellation switch may be on, and in a noise cancellation period after the sampling period, the first reset switch may be off. In an amplification period after the noise cancellation period, the first input switch may be off, the second input switch may be on, and the first noise cancellation switch may be off.

In this way, in the sampling period, the charge based on the first input signal is accumulated in the first sampling capacitor. In the noise cancellation period, the charge based on sampling noise can be accumulated in the first noise cancellation capacitor. In the amplification period, the charge corresponding to the voltage difference between the first input signal and the second input signal is accumulated in the first feedback capacitor, and the output signal of the voltage based on the voltage difference can be output.

This embodiment may also include a first feedback switch provided in series with the first feedback capacitor between the first input terminal and the first output terminal.

In this way, when the first feedback switch is on, a feedback loop can be formed between the first output terminal and the first input terminal of the operational amplifier, and when the first feedback switch is off, this feedback loop can be blocked.

In this embodiment, in the sampling period, the first input switch may be on, the second input switch may be off, and the first reset switch, the first noise cancellation switch, and the first feedback switch may be on, and in the noise cancellation period after the sampling period, the first reset switch and the first feedback switch may be off. In the amplification period after the noise cancellation period, the first input switch may be off, the second input switch may be on, the first noise cancellation switch may be off, and the first feedback switch may be on.

In this way, in the noise cancellation period, since the first feedback switch is off, the feedback loop between the first output terminal and the first input terminal of the operational amplifier is blocked, and the charge based on the sampling noise can be accumulated and held in the first noise cancellation capacitor. In the amplification period, since the first feedback switch is on, the feedback loop is formed, and an amplification operation based on the capacitance ratio between the first sampling capacitor and the first feedback capacitor can be implemented.

This embodiment may also include a third input switch provided between the first input node and a second node, a fourth input switch provided between the second input node and the second node, a second sampling capacitor provided between the second node and a second input terminal of the operational amplifier, and second feedback capacitor provided between the second input terminal and a second output terminal of the operational amplifier and having a capacitance value that is variable according to the gain. The embodiment may also include a second reset switch provided in parallel with the second feedback capacitor between the second input terminal and the second output terminal, and a second noise cancellation circuit provided in parallel with the second feedback capacitor and the second reset switch between the second input terminal and the second output terminal and including a second noise cancellation capacitor and a second noise cancellation switch coupled in series.

In this way, the voltage difference between the first input signal and the second input signal is amplified with the variable gain, the first output signal is output from the first output terminal of the operational amplifier, and the second output signal is output from the second output terminal. In the programmable gain amplifier having such a differential configuration, the first output signal and the second output signal formed by amplifying the voltage difference with a gain that is, for example, twice the gain in a programmable gain amplifier which does not have a differential configuration, can be output and therefore a further reduction in the noise or the like can be achieved.

In this embodiment, in the sampling period, the first input switch and the fourth input switch may be on, the second input switch and the third input switch may be off, and the first reset switch, the second reset switch, the first noise cancellation switch, and the second noise cancellation switch may be on. In the noise cancellation period after the sampling period, the first reset switch and the second reset switch may be off. In the amplification period after the noise cancellation period, the first input switch and the fourth input switch may be off, the second input switch and the third input switch may be on, and the first noise cancellation switch and the second noise cancellation switch may be off.

In this way, in the sampling period, the charge based on the first input signal is accumulated in the first sampling capacitor, and the charge based on the second input signal is accumulated in the second sampling capacitor. In the noise cancellation period, the charge based on the sampling noise can be accumulated in the first noise cancellation capacitor and the second noise cancellation capacitor. In the amplification period, the charge corresponding to the voltage difference between the first input signal and the second input signal is accumulated in the first feedback capacitor and the second feedback capacitor, and the first output signal and the second output signal of the voltage based on the voltage difference can be output.

This embodiment may also include a first feedback switch provided in series with the first feedback capacitor between the first input terminal and the first output terminal, and a second feedback switch provided in series with the second feedback capacitor between the second input terminal and the second output terminal.

In this way, when the first feedback switch and the second feedback switch are on, a feedback loop can be formed between the first output terminal and the first input terminal of the operational amplifier and between the second output terminal and the second input terminal, and when the first feedback switch and the second feedback switch are off, this feedback loop can be blocked.

In this embodiment, in the sampling period, the first input switch and the fourth input switch may be on, the second input switch and the third input switch may be off, and the first reset switch, the second reset switch, the first noise cancellation switch, the second noise cancellation switch, the first feedback switch, and the second feedback switch may be on. In the noise cancellation period after the sampling period, the first reset switch, the second reset switch, the first feedback switch, and the second feedback switch may be off. In the amplification period after the noise cancellation period, the first input switch and the fourth input switch may be off, the second input switch and the third input switch may be on, the first noise cancellation switch and the second noise cancellation switch may be off, and the first feedback switch and the second feedback switch may be on.

In this way, in the noise cancellation period, since the first feedback switch and the second feedback switch are off, the feedback loop between the first output terminal and the first input terminal of the operational amplifier and the feedback loop between the second output terminal and the second input terminal are blocked, and the charge based on the sampling noise can be accumulated and held in the first noise cancellation capacitor and the second noise cancellation capacitor. In the amplification period, since the first feedback switch and the second feedback switch are on, the feedback loop is formed and an amplification operation based on the capacitance ratio between the first sampling capacitor and the first feedback capacitor and the capacitance ratio between the second sampling capacitor and the second feedback capacitor can be implemented.

The circuit device according to this embodiment may include the programmable gain amplifier described above and an A/D converting circuit that performs A/D conversion of an output signal of the programmable gain amplifier.

In this way, the A/D converting circuit can perform A/D conversion of a signal over a wide amplitude range amplified by the programmable gain amplifier, and can implement highly accurate A/D conversion.

This embodiment may also include a sensor circuit that outputs a detection signal to the programmable gain amplifier as the first input signal or the second input signal.

In this way, a signal obtained by amplifying the detection signal of the sensor circuit by the programmable gain amplifier is A/D-converted by the A/D converting circuit, and a digital A/D conversion result can be obtained.

In this embodiment, a power supply voltage based on a common power supply may be supplied to the A/D converting circuit and the sensor circuit. In a period during which the programmable gain amplifier performs a sampling operation, the A/D converting circuit may perform a conversion operation, and in a period during which the programmable gain amplifier performs an amplification operation, the A/D converting circuit may perform a sampling operation.

In this way, the sampling period of the programmable gain amplifier can be ended early, for example, and the adverse effect of the noise generated in the A/D converting circuit after the end timing of the sampling period on the final A/D conversion result can be reduced.

While the embodiment has been described in detail above, a person skilled in the art can readily understand that many modifications can be made without substantially departing from the novel matters and effects of the present disclosure. Therefore, all such modifications are within the scope of the present disclosure. For example, a term described at least once together with a different term having a broader meaning or the same meaning in the description or the drawings can be replaced with the different term at any place in the description or the drawings. All combinations of the embodiment and the modifications are also included in the scope of the present disclosure. The configurations and operations or the like of the programmable gain amplifier and the circuit device are not limited to those described in the embodiment, and various modifications can be made.

What is claimed is:

1. A programmable gain amplifier that amplifies a voltage difference between a first input signal and a second input signal with a variable gain, the programmable gain amplifier comprising:
a first input switch provided between a first input node of the first input signal and a first node;
a second input switch provided between a second input node of the second input signal and the first node;
an operational amplifier;
a first sampling capacitor provided between the first node and a first input terminal of the operational amplifier;
a first feedback capacitor provided between the first input terminal and a first output terminal of the operational amplifier and having a capacitance value that is variable according to the gain;
a first reset switch provided in parallel with the first feedback capacitor between the first input terminal and the first output terminal; and
a first noise cancellation circuit provided in parallel with the first feedback capacitor and the first reset switch between the first input terminal and the first output terminal and including a first noise cancellation capacitor and a first noise cancellation switch coupled in series.

2. The programmable gain amplifier according to claim 1, wherein
in a sampling period, the first input switch is on, the second input switch is off, and the first reset switch and the first noise cancellation switch are on,
in a noise cancellation period after the sampling period, the first reset switch is off, and
in an amplification period after the noise cancellation period, the first input switch is off, the second input switch is on, and the first noise cancellation switch is off.

3. The programmable gain amplifier according to claim 1, further comprising:
a first feedback switch provided in series with the first feedback capacitor between the first input terminal and the first output terminal.

4. The programmable gain amplifier according to claim 3, wherein
in a sampling period, the first input switch is on, the second input switch is off, and the first reset switch, the first noise cancellation switch, and the first feedback switch are on,
in a noise cancellation period after the sampling period, the first reset switch and the first feedback switch are off, and
in an amplification period after the noise cancellation period, the first input switch is off, the second input switch is on, the first noise cancellation switch is off, and the first feedback switch is on.

5. The programmable gain amplifier according to claim 1, further comprising:
a third input switch provided between the first input node and a second node;
a fourth input switch provided between the second input node and the second node;
a second sampling capacitor provided between the second node and a second input terminal of the operational amplifier;
a second feedback f capacitor provided between the second input terminal and a second output terminal of the operational amplifier and having a capacitance value that is variable according to the gain;
a second reset switch provided in parallel with the second feedback capacitor between the second input terminal and the second output terminal; and
a second noise cancellation circuit provided in parallel with the second feedback capacitor and the second reset switch between the second input terminal and the second output terminal and including a second noise cancellation capacitor and a second noise cancellation switch coupled in series.

6. The programmable gain amplifier according to claim 5, wherein
in a sampling period, the first input switch and the fourth input switch are on, the second input switch and the third input switch are off, and the first reset switch, the second reset switch, the first noise cancellation switch, and the second noise cancellation switch are on,
in a noise cancellation period after the sampling period, the first reset switch and the second reset switch are off, and
in an amplification period after the noise cancellation period, the first input switch and the fourth input switch are off, the second input switch and the third input switch are on, and the first noise cancellation switch and the second noise cancellation switch are off.

7. The programmable gain amplifier according to claim 5, further comprising:
a first feedback switch provided in series with the first feedback capacitor between the first input terminal and the first output terminal; and
a second feedback switch provided in series with the second feedback capacitor between the second input terminal and the second output terminal.

8. The programmable gain amplifier according to claim 7, wherein
in a sampling period, the first input switch and the fourth input switch are on, the second input switch and the third input switch are off, and the first reset switch, the second reset switch, the first noise cancellation switch, the second noise cancellation switch, the first feedback switch, and the second feedback switch are on,
in a noise cancellation period after the sampling period, the first reset switch, the second reset switch, the first feedback switch, and the second feedback switch are off, and
in an amplification period after the noise cancellation period, the first input switch and the fourth input switch are off, the second input switch and the third input switch are on, the first noise cancellation switch and the second noise cancellation switch are off, and the first feedback switch and the second feedback switch are on.

9. A circuit device comprising:
the programmable gain amplifier according to claim 1; and
an A/D converting circuit that performs A/D conversion of an output signal of the programmable gain amplifier.

10. The circuit device according to claim 9, further comprising:
a sensor circuit that outputs a detection signal to the programmable gain amplifier as the first input signal or the second input signal.

11. The circuit device according to claim 10, wherein
a power supply voltage based on a common power supply is supplied to the A/D converting circuit and the sensor circuit, and
in a period during which the programmable gain amplifier performs a sampling operation, the A/D converting circuit performs a conversion operation, and in a period during which the programmable gain amplifier performs an amplification operation, the A/D converting circuit performs a sampling operation.
